(19) United States
(12) Patent Application Publication
(10) Pub. No.: US 2026/0123420 A1
(43) Pub. Date: Apr. 30, 2026

(54) SEMICONDUCTOR DEVICE AND SEMICONDUCTOR STRUCTURE

(71) Applicant: REALTEK SEMICONDUCTOR CORP., HsinChu (TW)

(72) Inventor: Nai-Jen Hsuan, HsinChu (TW)

(73) Assignee: REALTEK SEMICONDUCTOR CORP., HsinChu (TW)

(21) Appl. No.: 19/365,616

(22) Filed: Oct. 22, 2025

Related U.S. Application Data
(60) Provisional application No. 63/711,314, filed on Oct. 24, 2024.

(30) Foreign Application Priority Data
Jul. 28, 2025 (TW) 114128607

(51) Int. Cl. H01L 23/373; H01L 23/00; H01L 23/538; H01L 25/03; H01L 25/065

(52) U.S. Cl. CPC H10W 40/258; H10W 70/611; H10W 90/401; H10W 72/877; H10W 90/00; H10W 90/24; H10W 90/288; H10W 90/724; H10W 90/734

(57) ABSTRACT

A semiconductor device includes a substrate, a plurality of bumps, and a chip. The substrate has an upper surface and a lower surface. The substrate includes a plurality of lower contacts, a plurality of upper contacts, a first trace layer, a second trace layer, a metal heat dissipation unit, a cavity, and a voltage regulator. The first trace layer is between the upper surface and the lower surface. The second trace layer is on the first trace layer. The metal heat dissipation unit is between the first trace layer and the second trace layer. The cavity is on one side of the substrate. A portion of the first trace layer is exposed at a bottom of the cavity. The voltage regulator is in the cavity and electrically connected to the first trace layer. Each of the bumps is electrically connected to a corresponding one of the upper contacts.

### CROSS-REFERENCE TO RELATED APPLICATION

This application claims the benefit of U.S. provisional application Ser. No. 63/711,314, filed on Oct. 24, 2024 and claims the priority of patent application No. 114128607 filed in Taiwan, R.O.C. on Jul. 28, 2025. The entirety of the above-mentioned patent applications are hereby incorporated by references herein and made a part of the specification.

### BACKGROUND

### Technical Field

The instant disclosure relates to advanced packaging technology, specifically a semiconductor device and a semiconductor structure capable of improving transmission speed, heat dissipation performance, and power supply stability.

### Related Art

In upper-and-lower packaging structures known to the inventor, the upper packaging structure generally adopts a wire bonding process, while the lower packaging structure adopts a flip chip process.

However, such a structure has the following technical drawbacks. First, the wire bonding process adopted by the upper packaging structure limits high-speed signal transmission, thereby hindering the upper-and-lower packaging structure from achieving higher data transmission speeds. Second, due to the characteristics of the molding process, the heat dissipation of the upper die cannot be effectively conducted, which may cause overheating issues and thus affect the stability and performance of the upper die. Furthermore, the design and materials of the substrate limit the heat dissipation efficiency of the lower die, resulting in heat accumulation that further affects the performance and stability of the lower die. Last, since the power supply stabilization component (such as a voltage regulator) of the lower packaging structure is generally disposed outside the substrate of the lower packaging structure, the power supply path is relatively long, leading to decreased stability of power output and inability to effectively support stable high-performance operation.

### SUMMARY OF THE INVENTION

In some embodiments, a semiconductor device comprises a substrate, a plurality of bumps, and a chip. The substrate has an upper surface and a lower surface. The substrate comprises a plurality of lower contacts, a plurality of upper contacts, a first trace layer, a second trace layer, a plurality of first conductive vias, a plurality of second conductive vias, a plurality of third conductive vias, a metal heat dissipation unit, a cavity, and a voltage regulator. The lower contacts are on the lower surface. The upper contacts are on the upper surface. The first trace layer is between the upper surface and the lower surface. The second trace layer is between the upper surface and the lower surface and on the first trace layer. The first trace layer is electrically connected to the lower contacts through the first conductive vias. The second trace layer is electrically connected to the first trace layer through the second conductive vias. The upper contacts are electrically connected to the second trace layer through the third conductive vias. The metal heat dissipation unit is between the first trace layer and the second trace layer. The cavity is on one side of the substrate. A portion of the first trace layer is exposed at a bottom of the cavity. The voltage regulator is in the cavity and electrically connected to the first trace layer. Each of the bumps is electrically connected to a corresponding one of the upper contacts. An active surface of the chip is provided with a plurality of chip contacts. Each of the chip contacts is electrically connected to a corresponding one of the bumps. A position of the metal heat dissipation unit corresponds to a position of the chip.

In some embodiments, a projection area of the chip in a projection direction covers a projection area of the metal heat dissipation unit in the projection direction.

In some embodiments, the metal heat dissipation unit is directly under the chip.

In some embodiments, a semiconductor device comprises a substrate, a first chip, a second chip, a plurality of first metal posts, a plurality of second metal posts, a metal heat dissipation cap, and a molding layer. The substrate has an upper surface and a lower surface. The substrate comprises a plurality of lower contacts and a plurality of upper contacts. The lower contacts are on the lower surface. The upper contacts are on the upper surface. The upper contacts comprise a plurality of first contacts and a plurality of second contacts. An active surface of the first chip faces the upper surface of the substrate. The second chip is on a back surface of the first chip. An active surface of the second chip faces the upper surface of the substrate. The second chip partially overlaps the first chip in a projection direction. The active surface of the first chip is electrically connected to the first contacts through the first metal posts. The active surface of the second chip is electrically connected to the second contacts through the second metal posts. The metal heat dissipation cap covers the first chip and the second chip. The metal heat dissipation cap comprises a horizontal portion and a side portion. The horizontal portion is in thermal contact with a back surface of the second chip. One of two sides of the side portion is connected to one side of the horizontal portion, and the other side of the side portion is connected to the upper surface of the substrate. The molding layer encapsulates the first chip, the second chip, and the metal heat dissipation cap. The molding layer exposes the horizontal portion of the metal heat dissipation cap.

In some embodiments, the substrate further comprises a conductive via. The lower contacts comprise a ground contact. The other side of the side portion is electrically connected to the ground contact through the conductive via.

In some embodiments, a semiconductor structure comprises a first substrate, a plurality of bumps, a chip, a second substrate, a first chip, a second chip, a plurality of first metal posts, a plurality of second metal posts, a metal heat dissipation cap, a molding layer, and a plurality of third metal posts. The first substrate has an upper surface and a lower surface. The first substrate comprises a plurality of first lower contacts, a plurality of first upper contacts, a first trace layer, a second trace layer, a plurality of first conductive vias, a plurality of second conductive vias, a plurality of third conductive vias, a metal heat dissipation unit, a cavity, and a voltage regulator. The first lower contacts are on the lower surface of the first substrate. The first upper contacts are on the upper surface of the first substrate. The first upper contacts comprise a plurality of bump contacts and a plurality of first post contacts. The first trace layer is between the upper surface and the lower surface of the first substrate. The second trace layer is between the upper surface and the lower surface of the first substrate and on the first trace layer. The first trace layer is electrically connected to the first lower contacts through the first conductive vias. The second trace layer is electrically connected to the first trace layer through the second conductive vias. The bump contacts are electrically connected to the second trace layer through the third conductive vias. The metal heat dissipation unit is between the first trace layer and the second trace layer. The cavity is on one side of the first substrate. A portion of the first trace layer is exposed at a bottom of the cavity. The voltage regulator is in the cavity and electrically connected to the first trace layer. Each of the bumps is connected to a corresponding one of the bump contacts. An active surface of the chip is provided with a plurality of chip contacts. Each of the chip contacts is connected to a corresponding one of the bumps. The second substrate has an upper surface and a lower surface. The second substrate comprises a plurality of second lower contacts and a plurality of second upper contacts. The second lower contacts are on the lower surface of the second substrate. The second upper contacts are on the upper surface of the second substrate. The second upper contacts comprise a plurality of first contacts and a plurality of second contacts. An active surface of the first chip faces the upper surface of the second substrate. The second chip is on a back surface of the first chip. An active surface of the second chip faces the upper surface of the second substrate. The second chip partially overlaps the first chip in a projection direction. The active surface of the first chip is electrically connected to the first contacts through the first metal posts. The active surface of the second chip is electrically connected to the second contacts through the second metal posts. The metal heat dissipation cap covers the first chip and the second chip. The metal heat dissipation cap comprises a horizontal portion and a side portion. The horizontal portion is in thermal contact with a back surface of the second chip. One of two sides of the side portion is connected to one side of the horizontal portion, and the other side of the side portion is connected to the upper surface of the second substrate. The molding layer encapsulates the first chip, the second chip, and the metal heat dissipation cap. The molding layer exposes the horizontal portion of the metal heat dissipation cap. The first post contacts are electrically connected to the second post contacts through the third metal posts. A position of the metal heat dissipation unit corresponds to a position of the chip.

In some embodiments, the second substrate further comprises a conductive via. The other side of the side portion is electrically connected to the ground contact through the conductive via.

In some embodiments, a method for manufacturing a semiconductor structure comprises: providing a first substrate having an upper surface and a lower surface, wherein the first substrate comprises a plurality of first upper contacts on the upper surface of the first substrate, and the first upper contacts comprise a plurality of bump contacts and a plurality of first post contacts; providing a chip, wherein an active surface of the chip is provided with a plurality of chip contacts; forming a plurality of bumps on the chip contacts, wherein each of the chip contacts is connected to a corresponding one of the bumps; contacting each of the bumps to a corresponding one of the bump contacts; performing a reflow process to cause each of the bump contacts to be soldered to the corresponding one of the bumps; providing a second substrate having an upper surface and a lower surface, wherein the second substrate comprises a plurality of second upper contacts on the upper surface of the second substrate and a plurality of second lower contacts on the lower surface of the second substrate, the second upper contacts comprise a plurality of first contacts and a plurality of second contacts, and the second lower contacts comprise a plurality of second post contacts and a ground contact; providing a first chip; providing a second chip on a back surface of the first chip, wherein the second chip partially overlaps the first chip in a projection direction; forming a plurality of first metal posts on the first contacts and forming a plurality of second metal posts on the second contacts; contacting the first metal posts to an active surface of the first chip and contacting the second metal posts to an active surface of the second chip; performing a reflow process to cause the active surface of the first chip to be soldered to the first metal posts and to cause the active surface of the second chip to be soldered to the second metal posts; forming a metal heat dissipation cap covering the first chip and the second chip, wherein the metal heat dissipation cap comprises a horizontal portion and a side portion, the horizontal portion is in thermal contact with a back surface of the second chip, one of two sides of the side portion is connected to one side of the horizontal portion, and the other side of the side portion is connected to the upper surface of the second substrate; forming a molding layer, wherein the molding layer encapsulates the first chip, the second chip, and the metal heat dissipation cap, and the molding layer exposes the horizontal portion of the metal heat dissipation cap; forming a plurality of third metal posts on the second post contacts; contacting the third metal posts to the first post contacts; and performing a reflow process to cause the first post contacts to be soldered to the third metal posts.

In some embodiments, the first substrate further comprises a plurality of first lower contacts, a first trace layer, a second trace layer, a plurality of first conductive vias, a plurality of second conductive vias, a plurality of third conductive vias, a metal heat dissipation unit, a cavity, and a voltage regulator. The first lower contacts are on the lower surface of the first substrate. The first trace layer is between the upper surface and the lower surface of the first substrate. The second trace layer is between the upper surface and the lower surface of the first substrate and on the first trace layer. The first trace layer is electrically connected to the first lower contacts through the first conductive vias. The second trace layer is electrically connected to the first trace layer through the second conductive vias. The bump contacts are electrically connected to the second trace layer through the third conductive vias. The metal heat dissipation unit is between the first trace layer and the second trace layer. The cavity is on one side of the first substrate. A portion of the first trace layer is exposed at a bottom of the cavity. The voltage regulator is in the cavity and electrically connected to the first trace layer. Each of the bumps is connected to a corresponding one of the bump contacts. An active surface of the chip is provided with a plurality of chip contacts. Each of the chip contacts is connected to a corresponding one of the bumps. A position of the metal heat dissipation unit corresponds to a position of the chip.

The following will describe the detailed features and advantages of the instant disclosure in detail in the detailed description. The content of the description is sufficient for any person skilled in the art to comprehend the technical context of the instant disclosure and to implement it accordingly. According to the content, claims and drawings disclosed in the instant specification, any person skilled in the art can readily understand the goals and advantages of the instant disclosure.

### BRIEF DESCRIPTION OF THE DRAWINGS

The disclosure will become more fully understood from the detailed description given herein below for illustration only, and thus not limitative of the disclosure, wherein:

FIG. 1 illustrates a cross-sectional view of a semiconductor device according to an embodiment;

FIG. 2 illustrates a cross-sectional view of another semiconductor device according to an embodiment;

FIG. 3 illustrates a cross-sectional view of a semiconductor structure according to an embodiment;

FIG. 4A and FIG. 4B illustrate a flowchart of a method for manufacturing the semiconductor structure according to an embodiment; and

FIG. 5A to FIG. 5L illustrate views of the method for manufacturing the semiconductor structure according to the embodiment.

### DETAILED DESCRIPTION OF THE INVENTION

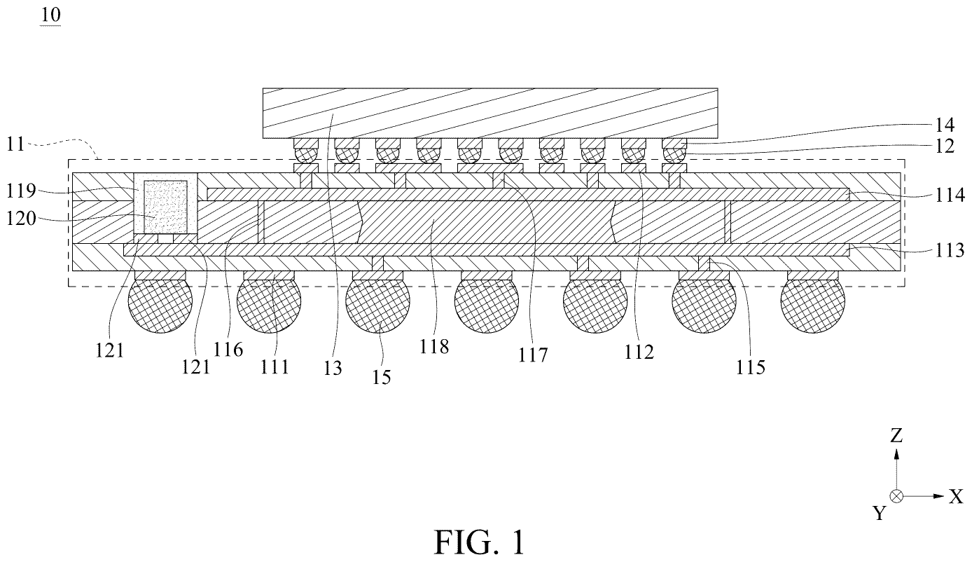

FIG. 1 illustrates a cross-sectional view of a semiconductor device 10 according to an embodiment. Please refer to FIG. 1. The semiconductor device 10 comprises a substrate 11, a plurality of bumps 12, and a chip 13. The substrate 11 has an upper surface and a lower surface. The substrate 11 comprises a plurality of lower contacts 111, a plurality of upper contacts 112, a first trace layer 113, a second trace layer 114, a plurality of first conductive vias 115, a plurality of second conductive vias 116, a plurality of third conductive vias 117, a metal heat dissipation unit 118, a cavity 119, and a voltage regulator 120. The lower contacts 111 are on the lower surface. The upper contacts 112 are on the upper surface. The first trace layer 113 is between the upper surface and the lower surface. The second trace layer 114 is between the upper surface and the lower surface and on the first trace layer 113. The first trace layer 113 is electrically connected to the lower contacts 111 through the first conductive vias 115. The second trace layer 114 is electrically connected to the first trace layer 113 through the second conductive vias 116. The upper contacts 112 are electrically connected to the second trace layer 114 through the third conductive vias 117. The metal heat dissipation unit 118 is between the first trace layer 113 and the second trace layer 114. The cavity 119 is on one side of the substrate 11. A portion of the first trace layer 113 is exposed at a bottom of the cavity 119. The voltage regulator 120 is in the cavity 119 and electrically connected to the first trace layer 113. Each of the bumps 12 is electrically connected to a corresponding one of the upper contacts 112. An active surface of the chip 13 is provided with a plurality of chip contacts 14. Each of the chip contacts 14 is electrically connected to a corresponding one of the bumps 12.

In some embodiments, each of the upper contacts 112 is directly soldered to a corresponding one of the bumps 12 in a vertical direction, but the instant disclosure is not limited thereto. In some embodiments, each of the upper contacts 112 may be but not limited to a solder ball. In some embodiments, each of the lower contacts 111 may be but not limited to formed on the lower surface of the substrate 11 by electroplating. In some embodiments, each of the upper contacts 112 may be but not limited to formed on the upper surface of the substrate 11 by electroplating. In some embodiments, a material of each of the lower contacts 111 and each of the upper contacts 112 may be but not limited to copper, aluminum, or tin. In some embodiments, sizes of the lower contacts 111 are identical. In some embodiments, sizes of the upper contacts 112 are identical.

In some embodiments, the bump 12 may be but not limited to a solder ball or a copper pillar. In some embodiments, each of the bumps 12 may be but not limited to electrically connected to a corresponding one of the chip contacts 14 in a manner of ball planting, solder paste printing, or electroplating. In some embodiments, each of the bumps 12 may be but not limited to eutectically bonded to a corresponding one of the upper contacts 112. In some embodiments, sizes of the bumps 12 are identical. In some embodiments, the bumps 12 are used to transmit high-speed signals, but the instant disclosure is not limited thereto; the bumps 12 may also be used to transmit low-speed signals.

In some embodiments, the metal heat dissipation unit 118 may be but not limited to a bar via. In some embodiments, a material of the metal heat dissipation unit 118 may be but not limited to copper. In some embodiments, a position of the metal heat dissipation unit 118 corresponds to a position of the chip 13. In some embodiments, a projection area of the chip 13 in a projection direction Z covers a projection area of the metal heat dissipation unit 118 in the projection direction Z. In other words, in some embodiments, the projection area of the metal heat dissipation unit 118 is entirely within the projection area of the chip 13, or the projection area of the metal heat dissipation unit 118 completely overlaps the projection area of the chip 13. That is, when viewed from the projection direction Z, an area of the chip 13 is greater than or at least equal to an area of the metal heat dissipation unit 118. In some embodiments, the metal heat dissipation unit 118 is directly under the chip 13.

In some embodiments, because the metal heat dissipation unit 118 is a bar via filled with copper or other high thermal conductivity materials, the metal heat dissipation unit 118 with a larger diameter compared with a normal via can provide higher thermal conductivity. Therefore, in some embodiments, the substrate 11 has an efficient heat conduction path in the projection direction Z. Heat generated inside the substrate 11 and by the chip 13 can be quickly and effectively guided to an outer layer of the semiconductor device 10 through the heat conduction path, thereby enhancing heat dissipation efficiency of the semiconductor device 10. That is, in some embodiments, through the metal heat dissipation unit 118, the semiconductor device 10 can avoid overheating, and performance and stability of the chip 13 are not affected by heat accumulation.

In some embodiments, a material of each of the first conductive vias 115, the second conductive vias 116, and the third conductive vias 117 may be but not limited to copper.

In some embodiments, the lower contacts 111 are further electrically connected to a plurality of solder balls 15. In some embodiments, the lower contacts 111 are electrically connected to an external circuit (not shown in the drawings) through the solder balls 15.

In some embodiments, the voltage regulator 120 is electrically connected to the first trace layer 113 through a plurality of regulator contacts 121. In some embodiments, the regulator contacts 121 may be but not limited to formed on an upper surface of the first trace layer 113 by electroplating.

In some embodiments, because the cavity 119 is in the substrate 11 instead of outside the substrate 11 and the voltage regulator 120 is in the cavity 119, the voltage regulator 120 can be arranged closer to core components (such as the chip 13) that require stable power supply. A short-distance power supply path reduces current transmission loss and impedance, thereby achieving a more stable voltage output. In addition, because the power supply path is shortened, power loss during power transmission is also reduced, and overall power consumption of the semiconductor device 10 is reduced. Furthermore, because the power supply path is shortened, signal transmission time is also shortened, which helps improve efficiency of internal components of the semiconductor device 10. That is, in some embodiments, by providing the cavity 119 in the substrate 11 and providing the voltage regulator 120 in the cavity 119, the power supply path of the semiconductor device 10 is shortened, stability of power output of the semiconductor device 10 is improved, and power consumption and delay of the semiconductor device 10 are reduced, thereby improving performance of the semiconductor device 10.

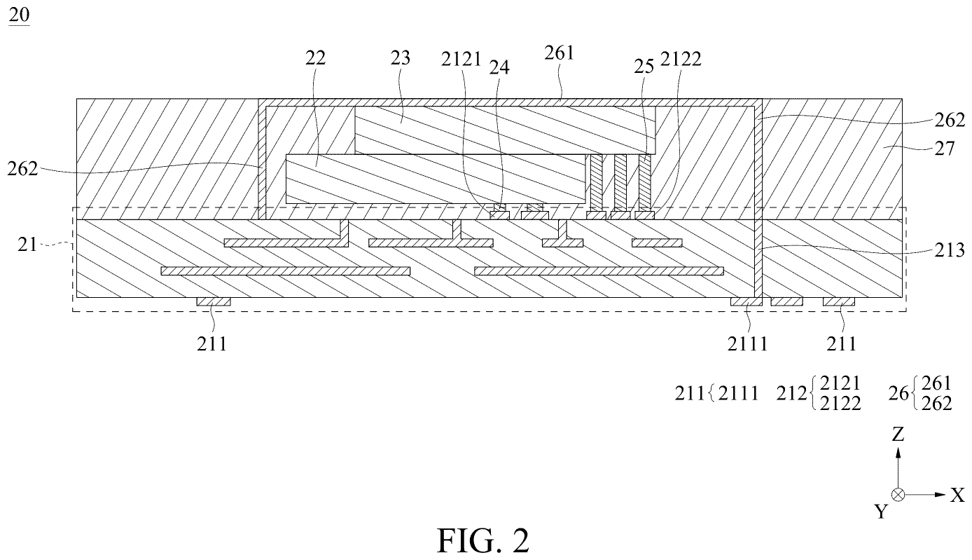

FIG. 2 illustrates a cross-sectional view of a semiconductor device 20 according to an embodiment. Please refer to FIG. 2. The semiconductor device 20 comprises a substrate 21, a first chip 22, a second chip 23, a plurality of first metal posts 24, a plurality of second metal posts 25, a metal heat dissipation cap 26, and a molding layer 27. The substrate 21 has an upper surface and a lower surface. The substrate 21 comprises a plurality of lower contacts 211 and a plurality of upper contacts 212. The lower contacts 211 are on the lower surface. The upper contacts 212 are on the upper surface. The upper contacts 212 comprise a plurality of first contacts 2121 and a plurality of second contacts 2122. An active surface of the first chip 22 faces the upper surface of the substrate 21. The second chip 23 is on a back surface of the first chip 22. An active surface of the second chip 23 faces the upper surface of the substrate 21. The second chip 23 partially overlaps the first chip 22 in a projection direction Z. The active surface of the first chip 22 is electrically connected to the first contacts 2121 through the first metal posts 24. The active surface of the second chip 23 is electrically connected to the second contacts 2122 through the second metal posts 25. The metal heat dissipation cap 26 covers the first chip 22 and the second chip 23. The metal heat dissipation cap 26 comprises a horizontal portion 261 and a side portion 262. The horizontal portion 261 is in thermal contact with a back surface of the second chip 23. One of two sides of the side portion 262 is connected to one side of the horizontal portion 261, and the other side of the side portion 262 is connected to the upper surface of the substrate 21. The molding layer 27 encapsulates the first chip 22, the second chip 23, and the metal heat dissipation cap 26, and the molding layer 27 exposes the horizontal portion 261 of the metal heat dissipation cap 26.

In some embodiments, each of the lower contacts 211 may be but not limited to formed on the lower surface of the substrate 21 by electroplating. In some embodiments, each of the upper contacts 212 may be but not limited to formed on the upper surface of the substrate 21 by electroplating. In some embodiments, a material of each of the lower contacts 211 and each of the upper contacts 212 may be but not limited to copper, aluminum, or tin. In some embodiments, sizes of the lower contacts 211 are identical. In some embodiments, sizes of the upper contacts 212 are identical.

In some embodiments, the active surface of the first chip 22 is provided with a plurality of first chip contacts, and the active surface of the first chip 22 is electrically connected to the first metal posts 24 through the first chip contacts so as to be electrically connected to the first contacts 2121 through the first metal posts 24. In some embodiments, the active surface of the second chip 23 is provided with a plurality of second chip contacts, and the active surface of the second chip 23 is electrically connected to the second metal posts 25 through the second chip contacts so as to be electrically connected to the second contacts 2122 through the second metal posts 25. In some embodiments, solder paste is applied on the active surface of the first chip 22, and the active surface of the first chip 22 is electrically connected to the first metal posts 24 through the solder paste applied thereon so as to be electrically connected to the first contacts 2121 through the first metal posts 24. In some embodiments, solder paste is applied on the active surface of the second chip 23, and the active surface of the second chip 23 is electrically connected to the second metal posts 25 through the solder paste applied thereon so as to be electrically connected to the second contacts 2122 through the second metal posts 25.

In some embodiments, the second chip 23 is on the back surface of the first chip 22 in thermal contact. In some embodiments, the second chip 23 is on the back surface of the first chip 22 by directly contacting the first chip 22. In some embodiments, a high thermal conductivity adhesive layer is between the second chip 23 and the first chip 22. The second chip 23 is on the back surface of the first chip 22 through the high thermal conductivity adhesive layer between the second chip 23 and the first chip 22.

In some embodiments, the horizontal portion 261 directly contacts the back surface of the second chip 23. In some embodiments, a high thermal conductivity adhesive layer is between the horizontal portion 261 and the back surface of the second chip 23. The horizontal portion 261 is connected to the back surface of the second chip 23 through the high thermal conductivity adhesive layer between the horizontal portion 261 and the back surface of the second chip 23.

In some embodiments, the formation of the molding layer 27 comprises a grinding process. In some embodiments, a material of the molding layer 27 above the horizontal portion 261 of the metal heat dissipation cap 26 is removed in the grinding process, so that the horizontal portion 261 of the metal heat dissipation cap 26 is exposed after the formation of the molding layer 27 is completed.

In some embodiments, a material of each of the first metal posts 24 and each of the second metal posts 25 may be but not limited to copper, gold, or an alloy. In some embodiments, a height of each of the first metal posts 24 may be dynamically adjusted according to user requirements or according to a distance to be set between the first chip 22 and the substrate 21. In some embodiments, a height of each of the second metal posts 25 may be dynamically adjusted according to user requirements or according to a distance to be set between the second chip 23 and the substrate 21. In some embodiments, a width of each of the first metal posts 24 may be dynamically adjusted according to user requirements, and the width of each of the first metal posts 24 may be different from one another. In some embodiments, a width of each of the second metal posts 25 may be dynamically adjusted according to user requirements, and the width of each of the second metal posts 25 may be different from one another.

In some embodiments, due to material characteristics of the first metal posts 24 and the second metal posts 25, the first metal posts 24 and the second metal posts 25 can provide higher electrical conductivity compared with the wire bonding technique known to the inventor, thereby effectively reducing power loss. In addition, the first metal posts 24 and the second metal posts 25 have good thermal conductivity, and the first metal posts 24 and the second metal posts 25 can quickly allow the heat generated during operation of the first chip 22 and the second chip 23 to be dissipated outward, thereby helping avoid performance degradation or damage of the first chip 22 and the second chip 23 caused by overheating. Furthermore, the first metal posts 24 and the second metal posts 25 can directly connect different components, and electrical paths are shorter compared with the wire bonding technique known to the inventor, thereby greatly reducing resistance and signal delay and enhancing support capability of the semiconductor device 20 for high-speed signals. That is, in some embodiments, through the first metal posts 24 and the second metal posts 25, the semiconductor device 20 can support high-speed signals, and heat dissipation capability of the semiconductor device 20 is also greatly improved.

In some embodiments, a material of the metal heat dissipation cap 26 may be but not limited to copper, gold, or an alloy.

In some embodiments, the horizontal portion 261 of the metal heat dissipation cap 26 is in thermal contact with the back surface of the second chip 23, and the horizontal portion 261 of the metal heat dissipation cap 26 is exposed. Therefore, the metal heat dissipation cap 26 can quickly absorb heat generated during operation of the first chip 22 and the second chip 23 and can quickly transfer the heat to outside through the exposed horizontal portion 261, thereby preventing performance degradation or damage of the first chip 22 and the second chip 23 caused by overheating. In addition, because the metal heat dissipation cap 26 is made of conductive metal, the metal heat dissipation cap 26 can serve as a metal shield for the first chip 22 and the second chip 23, thereby providing electromagnetic shielding for the first chip 22 and the second chip 23, effectively blocking electromagnetic interference between the first chip 22 and the second chip 23, and reducing signal noise between the first chip 22 and the second chip 23. That is, in some embodiments, through the metal heat dissipation cap 26, heat dissipation capability of the semiconductor device 20 is greatly improved, and the metal heat dissipation cap 26 may also provide an electromagnetic interference (EMI) shielding effect for the first chip 22 and the second chip 23.

In some embodiments, the substrate 21 further comprises a conductive via 213, and the lower contacts 211 further comprise a ground contact 2111. In some embodiments, the other side of the side portion 262 is electrically connected to the ground contact 2111 through the conductive via 213.

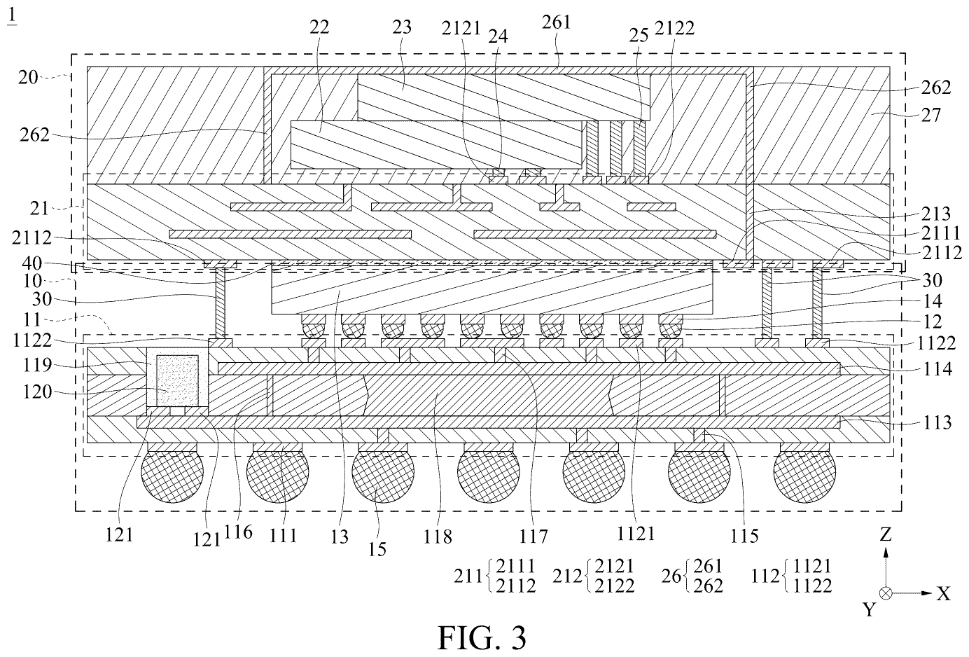

FIG. 3 illustrates a cross-sectional view of a semiconductor structure 1 according to an embodiment. Please refer to FIG. 3. The semiconductor structure 1 is an upper-and-lower package structure, in which an upper package structure of the semiconductor structure 1 is the semiconductor device 20 shown in FIG. 2, and a lower package structure of the semiconductor structure is the semiconductor device 10 shown in FIG. 1. The semiconductor structure 1 comprises the semiconductor device 10, the semiconductor device 20, and a plurality of third metal posts 30.

In some embodiments, the upper contacts 112 comprise a plurality of bump contacts 1121 and a plurality of first post contacts 1122. The bump contacts 1121 are electrically connected to the second trace layer 114 through the third conductive vias 117, and each of the bumps 12 is connected to a corresponding one of the bump contacts 1121. In some embodiments, the lower contacts 211 comprise a plurality of second post contacts 2112 and the ground contact 2111. In some embodiments, the first post contacts 1122 are electrically connected to the second post contacts 2112 through the third metal posts 30.

In some embodiments, a material of each of the third metal posts 30 may be but not limited to copper, gold, or an alloy. In some embodiments, a height of each of the third metal posts 30 may be dynamically adjusted according to a distance to be set between the semiconductor device 10 and the semiconductor device 20. In some embodiments, a width of each of the third metal posts 30 may be dynamically adjusted according to user requirements, and the width of each of the third metal posts 30 may be different from one another.

In some embodiments, the semiconductor structure 1 further comprises an adhesive layer 40. In some embodiments, a back surface of the chip 13 is adhered to the substrate 21 through the adhesive layer 40.

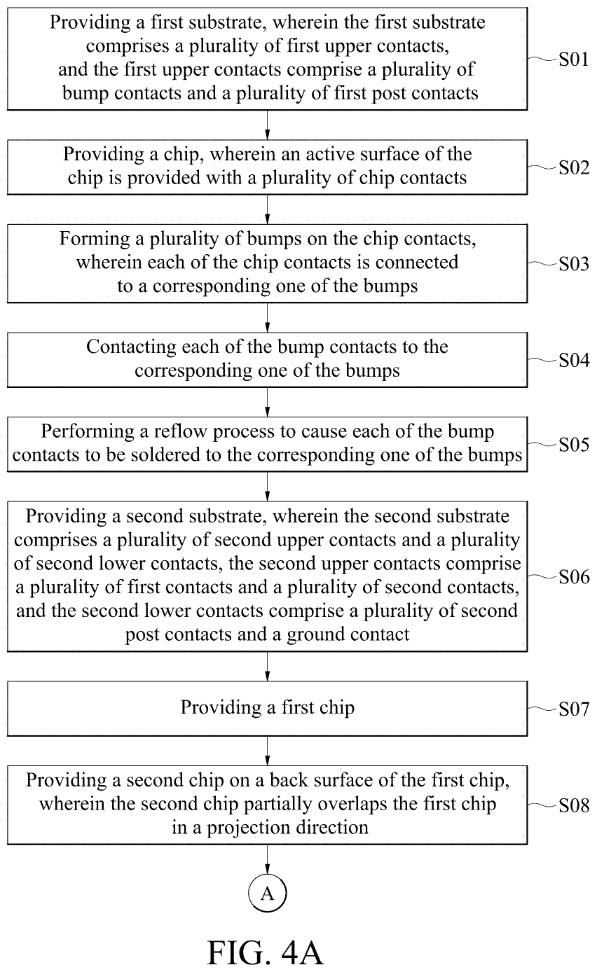

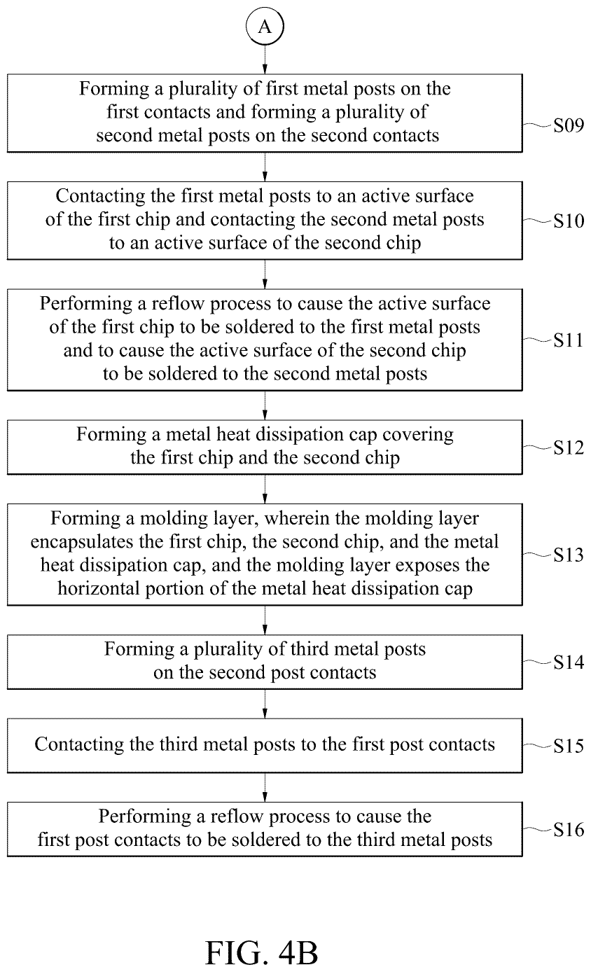

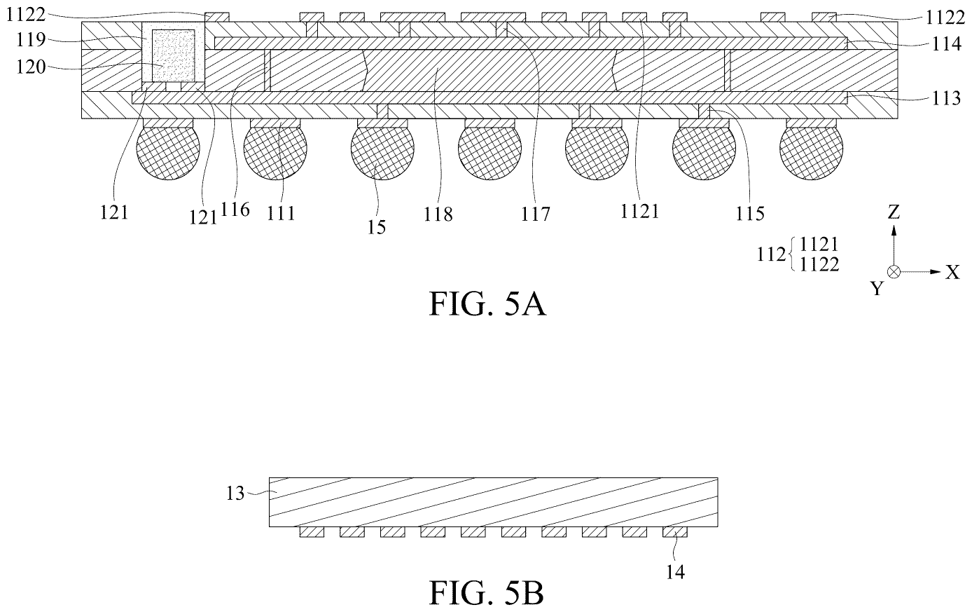

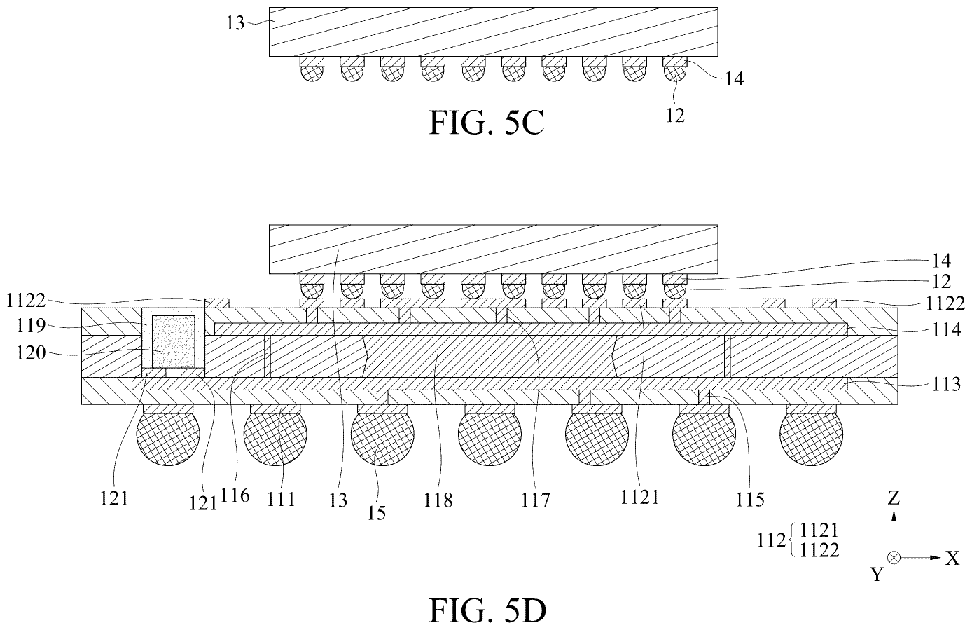

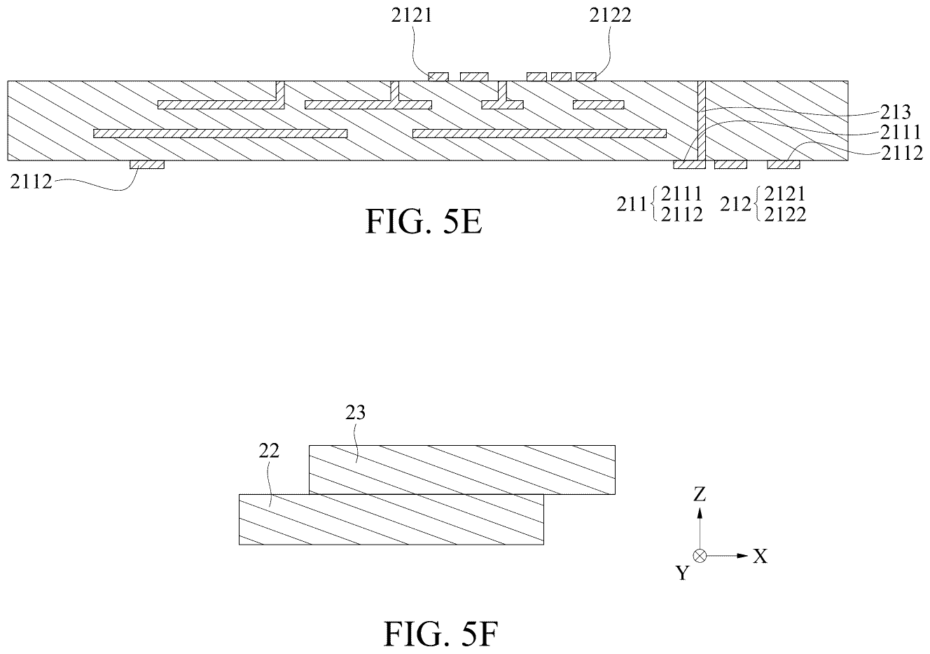

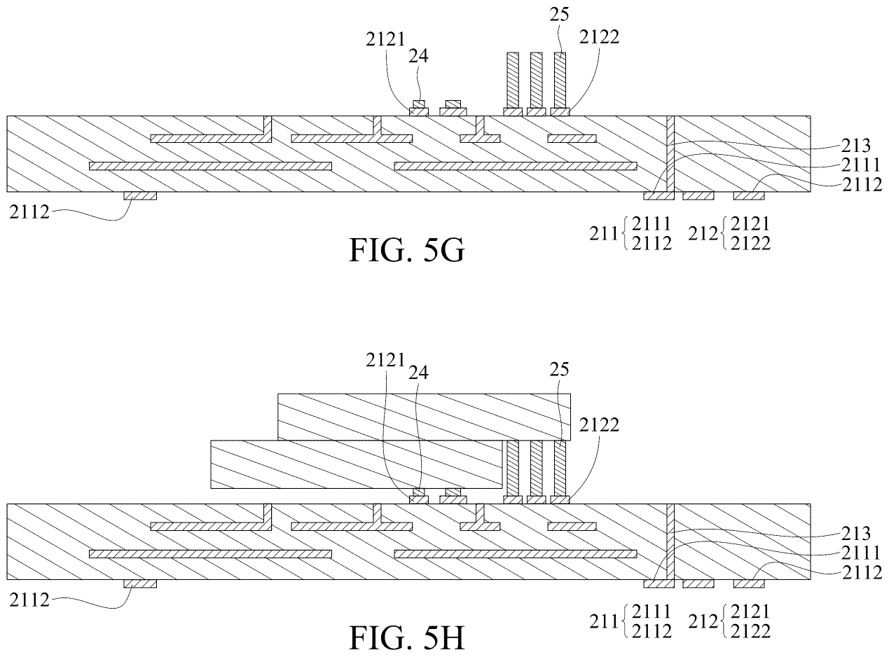

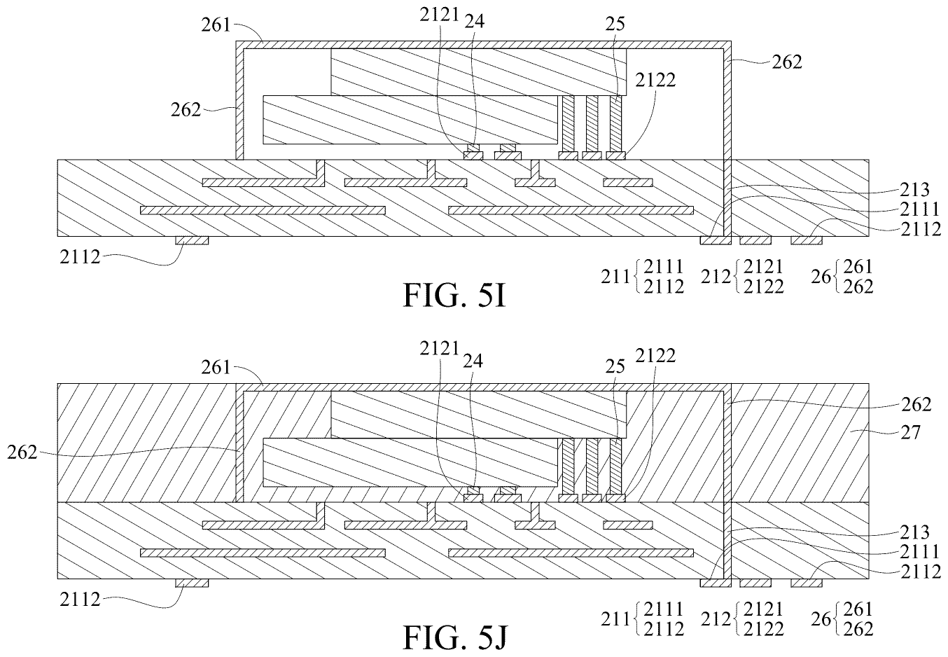

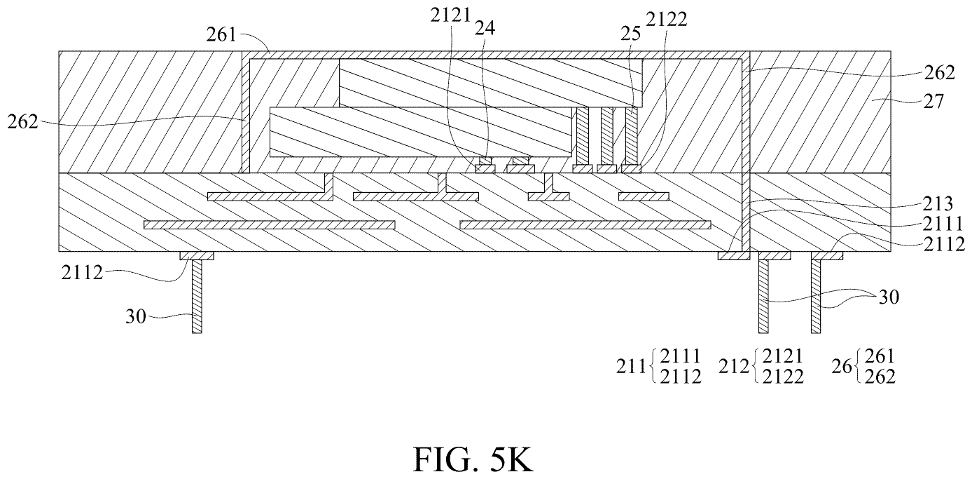

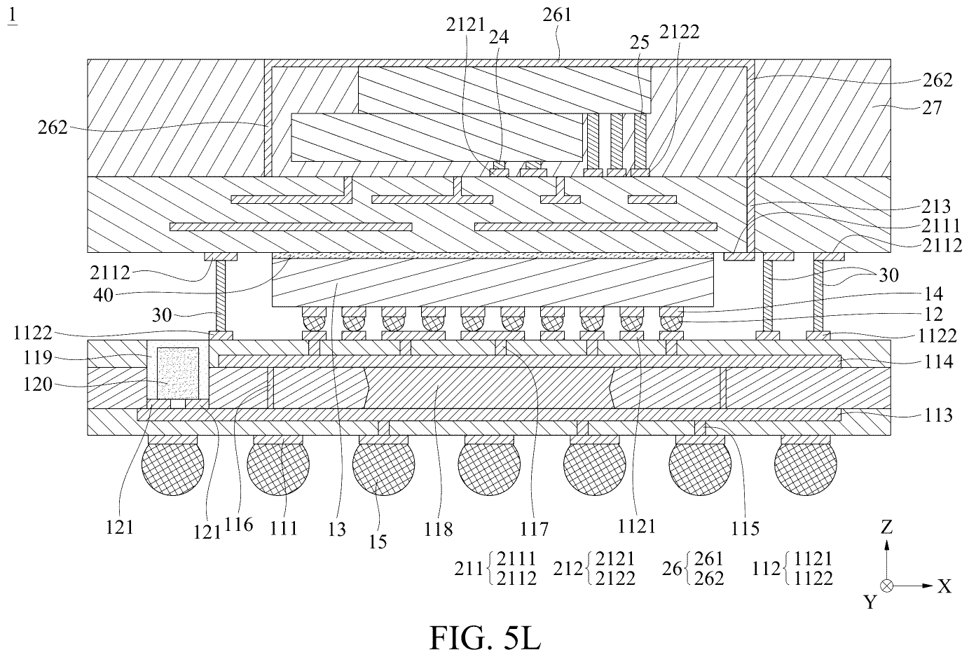

FIG. 4A and FIG. 4B illustrate a flowchart of a method for manufacturing the semiconductor structure 1 according to an embodiment. FIG. 5A to FIG. 5L illustrate views of the method for manufacturing the semiconductor structure 1 according to the embodiment. Please refer to FIG. 4A and FIG. 4B and FIG. 5A to FIG. 5L.

First, a substrate 11 is provided (step S01). The substrate 11 has an upper surface and a lower surface. The substrate 11 comprises a plurality of first upper contacts 112 on the upper surface of the substrate 11. The first upper contacts 112 comprise a plurality of bump contacts 1121 and a plurality of first post contacts 1122 (as shown in FIG. 5A). Next, a chip 13 is provided (step S02). An active surface of the chip 13 is provided with a plurality of chip contacts 14 (as shown in FIG. 5B). Next, a plurality of bumps 12 is formed on the chip contacts 14 (step S03). Each of the chip contacts 14 is connected to a corresponding one of the bumps 12 (as shown in FIG. 5C). Next, each of the bumps 12 is contacted to a corresponding one of the bump contacts 1121 (step S04). Next, a reflow process is performed to cause each of the bump contacts 1121 to be soldered to the corresponding one of the bumps 12 (step S05) (as shown in FIG. 5D). Step S01 to step S05 complete the lower package structure of the semiconductor structure 1 (that is, in this embodiment, the semiconductor device 10).

Next, a substrate 21 is provided (step S06). The substrate 21 has an upper surface and a lower surface. The substrate 21 comprises a plurality of second upper contacts 212 on the upper surface of the substrate 21 and a plurality of second lower contacts 211 on the lower surface of the substrate 21. The second upper contacts 212 comprise a plurality of first contacts 2121 and a plurality of second contacts 2122. The second lower contacts 211 comprise a plurality of second post contacts 2112 and a ground contact 2111 (as shown in FIG. 5E). Next, a first chip 22 is provided (step S07). Next, a second chip 23 is provided (step S08). The second chip 23 is on a back surface of the first chip 22, and the second chip 23 partially overlaps the first chip 22 in a projection direction Z (as shown in FIG. 5F). Next, a plurality of first metal posts 24 is formed on the first contacts 2121, and a plurality of second metal posts 25 is formed on the second contacts 2122 (step S09) (as shown in FIG. 5G). Next, each of the first metal posts 24 is contacted to an active surface of the first chip 22, and each of the second metal posts 25 is contacted to an active surface of the second chip 23 (step S10). Next, a reflow process is performed to cause the active surface of the first chip 22 to be soldered to the first metal posts 24 and to cause the active surface of the second chip 23 to be soldered to the second metal posts 25 (step S11) (as shown in FIG. 5H). Next, a metal heat dissipation cap 26 is formed (step S12). The metal heat dissipation cap 26 covers the first chip 22 and the second chip 23. The metal heat dissipation cap 26 comprises a horizontal portion 261 and a side portion 262. The horizontal portion 261 is in thermal contact with a back surface of the second chip 23. One of two sides of the side portion 262 is connected to one side of the horizontal portion 261, and the other side of the side portion 262 is connected to the upper surface of the substrate 21 (as shown in FIG. 5I). Next, a molding layer 27 is formed (step S13). The molding layer 27 encapsulates the first chip 22, the second chip 23, and the metal heat dissipation cap 26, and the molding layer 27 exposes the horizontal portion 261 of the metal heat dissipation cap 26 (as shown in FIG. 5J). Step S06 to step S13 complete the upper package structure of the semiconductor structure 1 (that is, in this embodiment, the semiconductor device 20).

Next, a plurality of third metal posts 30 is formed on the second post contacts 2112 (step S14) (as shown in FIG. 5K). Next, the third metal posts 30 are contacted to the first post contacts 1122 (step S15). Last, a reflow process is performed to cause the first post contacts 1122 to be soldered to the third metal posts 30 (step S16) (as shown in FIG. 5L). Steps S14 to S16 complete electrical connection between the upper package structure and the lower package structure of the semiconductor structure 1.

In some embodiments, in step S09, a method for forming the first metal posts 24 on the first contacts 2121 and forming the second metal posts 25 on the second contacts 2122 is depositing metal on the first contacts 2121 and depositing metal on the second contacts 2122. In some embodiments, the first metal posts 24 and the second metal posts 25 are pre-formed metal posts. In some embodiments, in step S09, a method for forming the first metal posts 24 on the first contacts 2121 and forming the second metal posts 25 on the second contacts 2122 is directly placing pre-formed first metal posts 24 on the first contacts 2121 and directly placing pre-formed second metal posts 25 on the second contacts 2122.

In some embodiments, in step S14, a method for forming the third metal posts 30 on the second post contacts 2112 is depositing metal on the second post contacts 2112. In some embodiments, the third metal posts 30 are pre-formed metal posts. In some embodiments, in step S14, a method for forming the third metal posts 30 on the second post contacts 2112 is directly placing pre-formed third metal posts 30 on the second post contacts 2112.

In the embodiment of FIG. 4A and FIG. 4B, the first metal posts 24 are first formed on the first contacts 2121 and then soldered to the active surface of the first chip 22, but the instant disclosure is not limited thereto. In some embodiments, the first metal posts 24 are first formed on the active surface of the first chip 22 and then soldered to the first contacts 2121.

In the embodiment of FIG. 4A and FIG. 4B, the second metal posts 25 are first formed on the second contacts 2122 and then soldered to the active surface of the second chip 23, but the instant disclosure is not limited thereto. In some embodiments, the second metal posts 25 are first formed on the active surface of the second chip 23 and then soldered to the second contacts 2122.

In the embodiment of FIG. 4A and FIG. 4B, the third metal posts 30 are first formed on the second post contacts 2112 and then soldered to the first post contacts 1122, but the instant disclosure is not limited thereto. In some embodiments, the third metal posts 30 are first formed on the first post contacts 1122 and then soldered to the second post contacts 2112.

In some embodiments, the method for manufacturing the semiconductor structure 1 further comprises forming a conductive via 213 in the substrate 21. In some embodiments, the other side of the side portion 262 of the metal heat dissipation cap 26 is electrically connected to the ground contact 2111 through the conductive via 213.

In some embodiments, the method for manufacturing the semiconductor structure 1 further comprises forming an adhesive layer 40. In some embodiments, a back surface of the chip 13 is adhered to the substrate 21 through the adhesive layer 40.

To sum up, in some embodiments, through the metal heat dissipation unit 118, the lower package structure (that is, the semiconductor device 10) of the semiconductor structure 1 can avoid overheating, and performance and stability of the chip 13 are not affected by heat accumulation. In some embodiments, by configuring the cavity 119 in the substrate 11 and disposing the voltage regulator 120 in the cavity 119, the power supply path of the semiconductor device 10 is shortened, so that power output stability of the semiconductor device 10 is improved, power consumption and delay of the semiconductor device 10 are reduced, and performance of the semiconductor device 10 is enhanced. In some embodiments, through the configuration of the first metal posts 24 and the second metal posts 25, the upper package structure (that is, the semiconductor device 20) of the semiconductor structure 1 can support high-speed signals, and heat dissipation capability of the semiconductor device 20 is also greatly improved. In some embodiments, through the metal heat dissipation cap 26, heat dissipation capability of the semiconductor device 20 is greatly improved, and the metal heat dissipation cap 26 may also provide an electromagnetic interference (EMI) shielding effect for the first chip 22 and the second chip 23.

Although the instant disclosure has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A semiconductor device comprising:
a substrate having an upper surface and a lower surface, wherein the substrate comprises:
a plurality of lower contacts on the lower surface;
a plurality of upper contacts on the upper surface;
a first trace layer between the upper surface and the lower surface;
a second trace layer between the upper surface and the lower surface and on the first trace layer;
a plurality of first conductive vias, wherein the first trace layer is electrically connected to the lower contacts through the first conductive vias;
a plurality of second conductive vias, wherein the second trace layer is electrically connected to the first trace layer through the second conductive vias;
a plurality of third conductive vias, wherein the upper contacts are electrically connected to the second trace layer through the third conductive vias;
a metal heat dissipation unit between the first trace layer and the second trace layer;
a cavity on one side of the substrate, wherein a portion of the first trace layer is exposed at a bottom of the cavity; and
a voltage regulator in the cavity and electrically connected to the first trace layer;
a plurality of bumps, wherein each of the bumps is electrically connected to a corresponding one of the upper contacts; and
a chip, wherein an active surface of the chip is provided with a plurality of chip contacts, and each of the chip contacts is electrically connected to a corresponding one of the bumps;
wherein a position of the metal heat dissipation unit corresponds to a position of the chip.

2. The semiconductor device according to claim 1, wherein a projection area of the chip in a projection direction covers a projection area of the metal heat dissipation unit in the projection direction.

3. The semiconductor device according to claim 2, wherein the metal heat dissipation unit is directly under the chip.

4. A semiconductor device comprising:
a substrate having an upper surface and a lower surface, wherein the substrate comprises:
a plurality of lower contacts on the lower surface; and
a plurality of upper contacts on the upper surface, wherein the upper contacts comprise a plurality of first contacts and a plurality of second contacts;
a first chip, wherein an active surface of the first chip faces the upper surface of the substrate;
a second chip on a back surface of the first chip, wherein an active surface of the second chip faces the upper surface of the substrate, and the second chip partially overlaps the first chip in a projection direction;
a plurality of first metal posts, wherein the active surface of the first chip is electrically connected to the first contacts through the first metal posts;
a plurality of second metal posts, wherein the active surface of the second chip is electrically connected to the second contacts through the second metal posts;
a metal heat dissipation cap covering the first chip and the second chip, wherein the metal heat dissipation cap comprises a horizontal portion and a side portion, the horizontal portion is in thermal contact with a back surface of the second chip, one of two sides of the side portion is connected to one side of the horizontal portion, and the other side of the side portion is connected to the upper surface of the substrate; and
a molding layer, wherein the molding layer encapsulates the first chip, the second chip, and the metal heat dissipation cap, and the molding layer exposes the horizontal portion of the metal heat dissipation cap.

5. The semiconductor device according to claim 4, wherein the substrate further comprises a conductive via, the lower contacts comprise a ground contact, and the other side of the side portion is electrically connected to the ground contact through the conductive via.

6. A semiconductor structure comprising:
a first substrate having an upper surface and a lower surface, wherein the first substrate comprises:
a plurality of first lower contacts on the lower surface of the first substrate;
a plurality of first upper contacts on the upper surface of the first substrate, wherein the first upper contacts comprise a plurality of bump contacts and a plurality of first post contacts;
a first trace layer between the upper surface of the first substrate and the lower surface of the first substrate;
a second trace layer between the upper surface of the first substrate and the lower surface of the first substrate and on the first trace layer;
a plurality of first conductive vias, wherein the first trace layer is electrically connected to the first lower contacts through the first conductive vias;
a plurality of second conductive vias, wherein the second trace layer is electrically connected to the first trace layer through the second conductive vias;
a plurality of third conductive vias, wherein the bump contacts are electrically connected to the second trace layer through the third conductive vias;
a metal heat dissipation unit between the first trace layer and the second trace layer;
a cavity on one side of the first substrate, wherein a portion of the first trace layer is exposed at a bottom of the cavity; and
a voltage regulator in the cavity and electrically connected to the first trace layer;
a plurality of bumps, wherein each of the bumps is connected to a corresponding one of the bump contacts;
a chip, wherein an active surface of the chip is provided with a plurality of chip contacts, and each of the chip contacts is connected to a corresponding one of the bumps;
a second substrate having an upper surface and a lower surface, wherein the second substrate comprises:
a plurality of second lower contacts on the lower surface of the second substrate, wherein the second lower contacts comprise a plurality of second post contacts and a ground contact; and
a plurality of second upper contacts on the upper surface of the second substrate, wherein the second upper contacts comprise a plurality of first contacts and a plurality of second contacts;
a first chip, wherein an active surface of the first chip faces the upper surface of the second substrate;
a second chip on a back surface of the first chip, wherein an active surface of the second chip faces the upper surface of the second substrate, and the second chip partially overlaps the first chip in a projection direction;
a plurality of first metal posts, wherein the active surface of the first chip is electrically connected to the first contacts through the first metal posts;
a plurality of second metal posts, wherein the active surface of the second chip is electrically connected to the second contacts through the second metal posts;
a metal heat dissipation cap covering the first chip and the second chip, wherein the metal heat dissipation cap comprises a horizontal portion and a side portion, the horizontal portion is in thermal contact with a back surface of the second chip, one of two sides of the side portion is connected to one side of the horizontal portion, and the other side of the side portion is connected to the upper surface of the second substrate;
a molding layer, wherein the molding layer encapsulates the first chip, the second chip, and the metal heat dissipation cap, and the molding layer exposes the horizontal portion of the metal heat dissipation cap; and
a plurality of third metal posts, wherein the first post contacts are electrically connected to the second post contacts through the third metal posts;
wherein a position of the metal heat dissipation unit corresponds to a position of the chip.

7. The semiconductor structure according to claim 6, wherein a projection area of the chip in the projection direction covers a projection area of the metal heat dissipation unit in the projection direction.

8. The semiconductor structure according to claim 6, wherein the metal heat dissipation unit is directly under the chip.

9. The semiconductor structure according to claim 6, wherein the second substrate further comprises a conductive via, and the other side of the side portion is electrically connected to the ground contact through the conductive via.
